(19) United States
(12) Patent Application Publication
(10) Pub. No.: US 2026/0075888 A1
(43) Pub. Date: Mar. 12, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Katsuhisa TANAKA, Himeji Hyogo (JP); Hiroshi KONO, Himeji Hyogo (JP)

(21) Appl. No.: 18/982,226

(22) Filed: Dec. 16, 2024

(30) Foreign Application Priority Data
Sep. 10, 2024 (JP) 2024-156632

(51) Int. Cl. H10D 62/10; H10D 30/66; H10D 62/40; H10D 62/832; H10D 64/27

(52) U.S. Cl. CPC H10D 62/111; H10D 30/668; H10D 62/405; H10D 64/513; H10D 62/8325

(57) ABSTRACT

According to one embodiment, a semiconductor device includes first to third electrodes, a semiconductor member, and a first insulating member. The third electrode includes a first electrode portion. The semiconductor member includes a first semiconductor region of a first conductivity type, a second semiconductor region of a second conductivity type, a third semiconductor region of the first conductivity type, a fourth semiconductor region of the second conductivity type, and a fifth semiconductor region of the second conductivity type. A position of the first insulating member in a third direction is different from a position of the first electrode portion in the third direction. A first distance along a first direction between the first electrode and the fourth semiconductor region is longer than a second distance along the first direction between the first electrode and the first semiconductor portion.

### CROSS-REFERENCE TO RELATED APPLICATIONS

This application is based upon and claims the benefit of priority from Japanese Patent Application No. 2024-156632, filed on Sep. 10, 2024; the entire contents of which are incorporated herein by reference.

### FIELD

Embodiments described herein relate generally to a semiconductor device.

### BACKGROUND

For example, in semiconductor devices, improvements in characteristics are desired.

### BRIEF DESCRIPTION OF THE DRAWINGS

FIG. 1 is a schematic cross-sectional view illustrating a semiconductor device according to a first embodiment;

FIG. 2 is a schematic cross-sectional view illustrating the semiconductor device according to the first embodiment;

FIG. 3 is a schematic cross-sectional view illustrating the semiconductor device according to the first embodiment;

FIG. 4 is a schematic cross-sectional view illustrating the semiconductor device according to the first embodiment;

FIG. 5 is a schematic cross-sectional view illustrating the semiconductor device according to the first embodiment;

FIG. 6 is a schematic plan view illustrating the semiconductor device according to the first embodiment;

FIG. 7 is a schematic plan view illustrating the semiconductor device according to the first embodiment;

FIG. 8 is a schematic plan view illustrating a semiconductor device according to the first embodiment;

FIG. 9 is a schematic cross-sectional view illustrating the semiconductor device according to the first embodiment;

FIG. 10 is a schematic cross-sectional view illustrating the semiconductor device according to the first embodiment;

FIG. 11 is a schematic plan view illustrating a semiconductor device according to the first embodiment;

FIG. 12 is a schematic cross-sectional view illustrating the semiconductor device according to the first embodiment;

FIG. 13 is a schematic cross-sectional view illustrating the semiconductor device according to the first embodiment;

FIG. 14 is a schematic plan view illustrating a semiconductor device of the first embodiment;

FIG. 15 is a schematic cross-sectional view illustrating the semiconductor device of the first embodiment;

FIG. 16 is a schematic cross-sectional view illustrating the semiconductor device of the first embodiment;

FIG. 17 is a schematic cross-sectional view illustrating the semiconductor device of the first embodiment;

FIG. 18 is a schematic cross-sectional view illustrating the semiconductor device of the first embodiment;

FIG. 19 is a schematic cross-sectional view illustrating the semiconductor device of the first embodiment;

FIG. 20 is a schematic cross-sectional view illustrating the semiconductor device of the first embodiment; and

FIG. 21 is a schematic cross-sectional view illustrating a semiconductor device according to the second embodiment.

### DETAILED DESCRIPTION

According to one embodiment, a semiconductor device includes a first electrode, a second electrode, a semiconductor member, a third electrode, and a first insulating member. The semiconductor member is provided between the first electrode and the second electrode. The third electrode includes a first electrode portion. The semiconductor member includes a first semiconductor region of a first conductivity type, a second semiconductor region of a second conductivity type, a third semiconductor region of the first conductivity type, a fourth semiconductor region of the second conductivity type, and a fifth semiconductor region of the second conductivity type. The first semiconductor region includes a first partial region, a second partial region, a third partial region, and a fourth partial region. The fifth semiconductor region includes a first semiconductor portion and a second semiconductor portion continuous with the first semiconductor portion. The second semiconductor portion is electrically connected to the fourth semiconductor region. The first partial region is between the first electrode and the first electrode portion in a first direction from the first electrode to the second electrode. The second semiconductor region is between the second partial region and the third semiconductor region in the first direction. A second direction from the first electrode portion to the second semiconductor region crosses the first direction. A direction from the first electrode portion to the third semiconductor region is along the second direction. The fourth semiconductor region is between the first partial region and the first electrode portion. A first insulating member position of the first insulating member in a third direction crossing a plane including the first direction and the second direction is different from a first electrode portion position of the first electrode portion in the third direction. The first semiconductor portion is between the third partial region and the first insulating member. The second semiconductor portion is between the first insulating member and the fourth partial region in a direction crossing the first direction. A first distance along the first direction between the first electrode and the fourth semiconductor region is longer than a second distance along the first direction between the first electrode and the first semiconductor portion.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

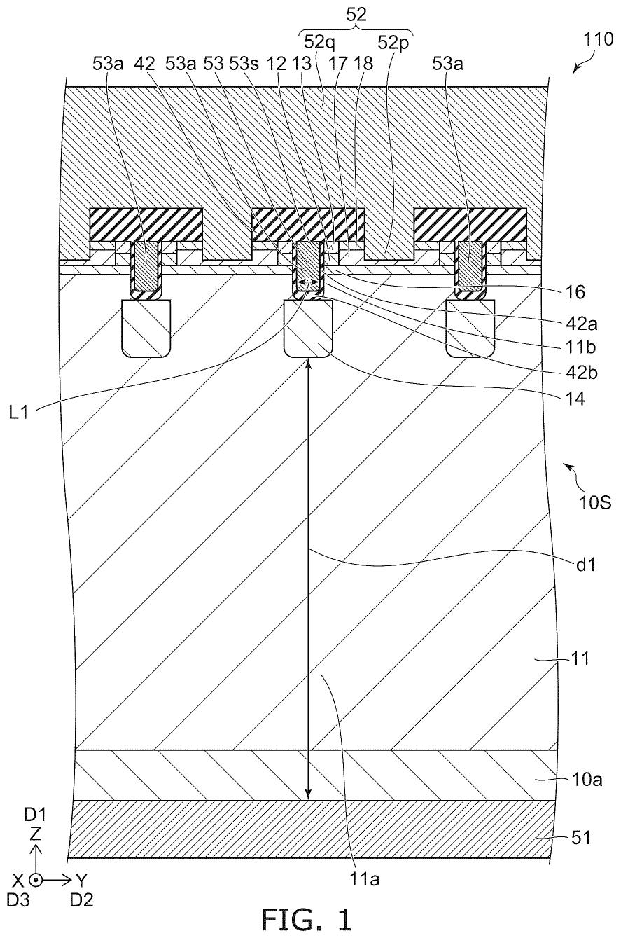

FIGS. 1 to 5 are schematic cross-sectional views illustrating a semiconductor device according to a first embodiment.

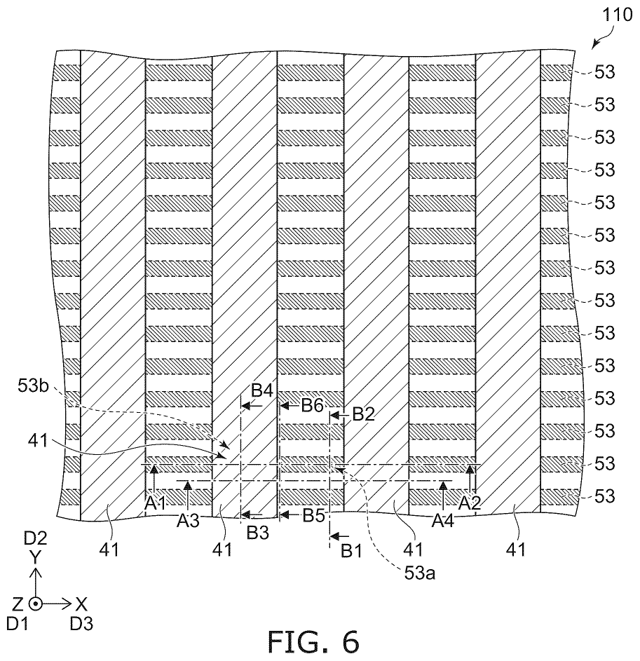

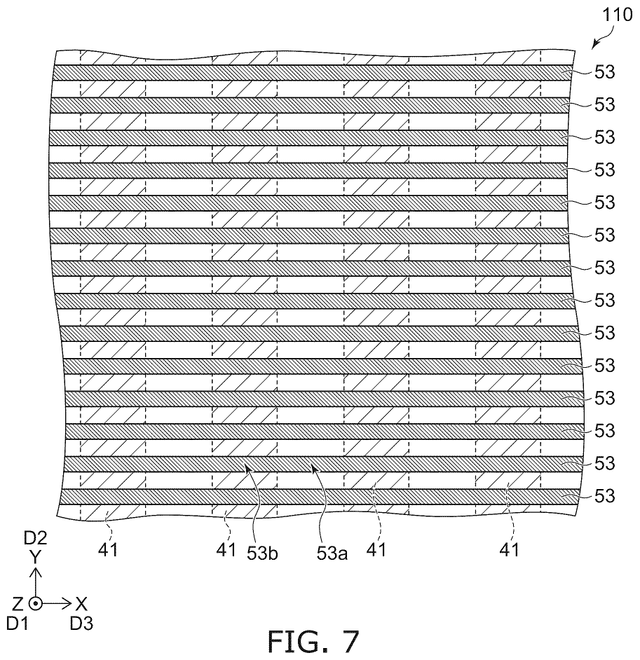

FIGS. 6 and 7 are schematic plan views illustrating the semiconductor device according to the first embodiment.

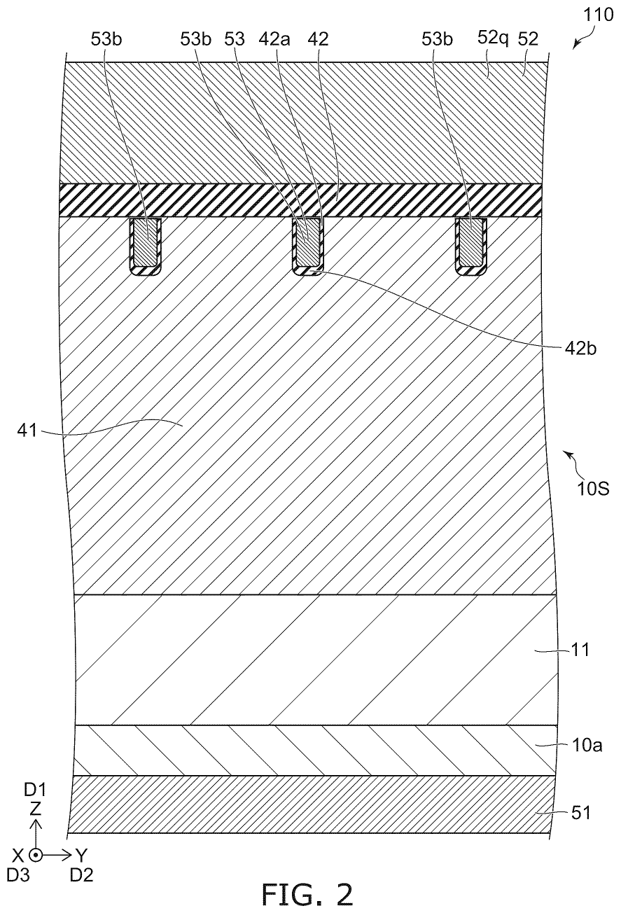

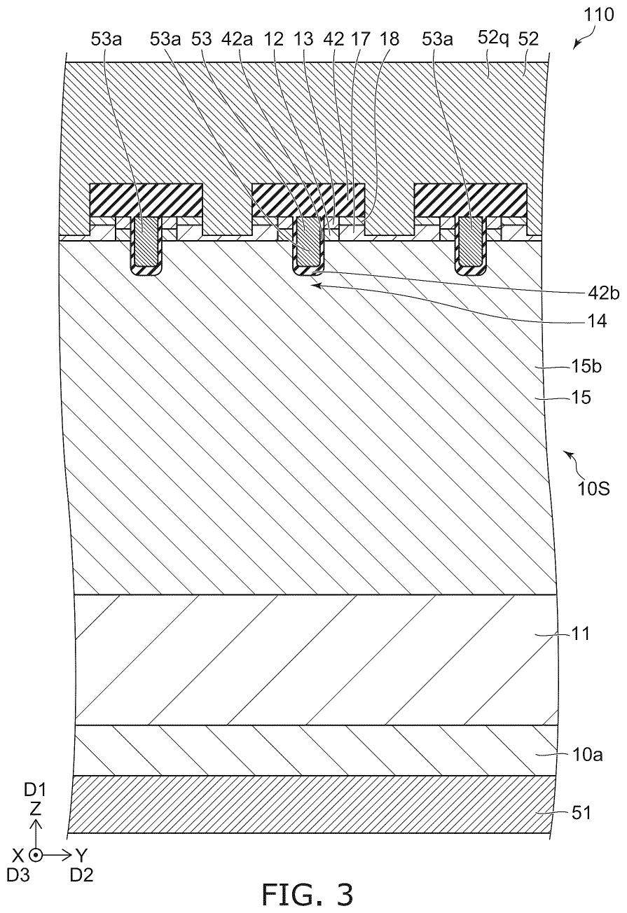

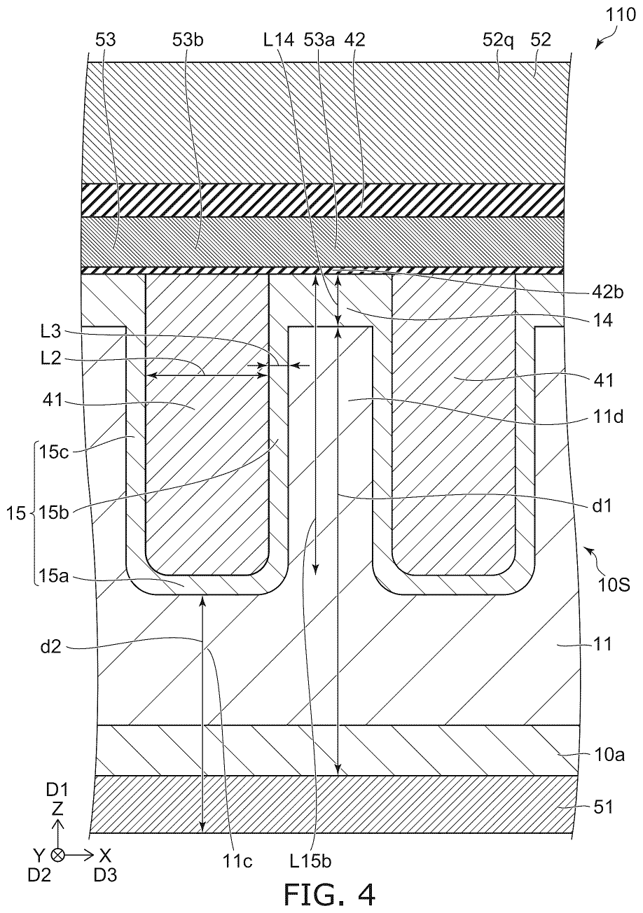

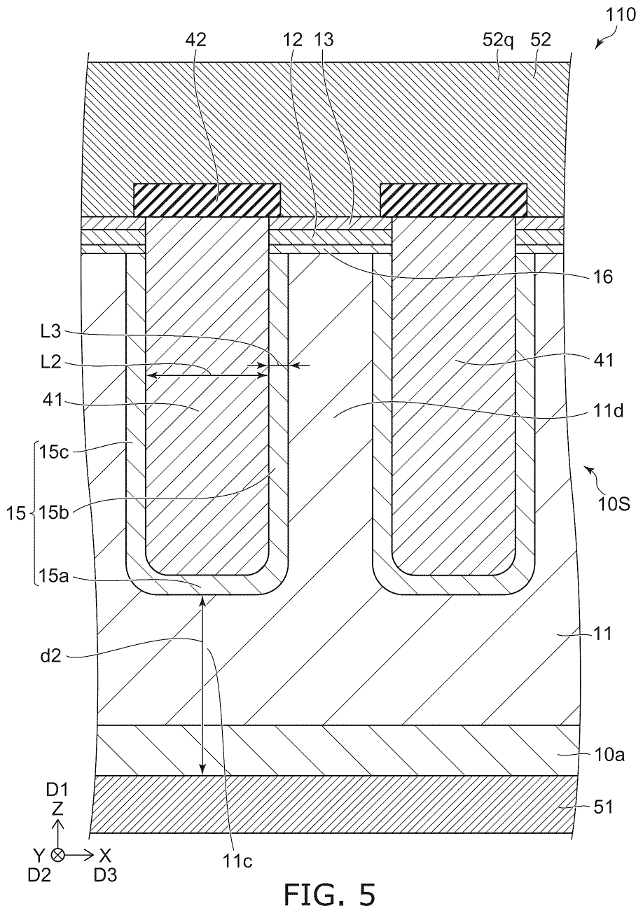

FIG. 1 is a cross-sectional view taken along line the B1-B2 in FIG. 6. FIG. 2 is a cross-sectional view taken along the line B3-B4 in FIG. 6. FIG. 3 is a cross-sectional view taken along the line B5-B6 in FIG. 6. FIG. 4 is a cross-sectional view taken along the line A1-A2 in FIG. 6. FIG. 5 is a cross-sectional view taken along line the A3-A4 in FIG. 6.

As shown in FIGS. 1 to 5, a semiconductor device 110 according to the embodiment includes a first electrode 51, a second electrode 52, a third electrode 53, a semiconductor member 10S, and a first insulating member 41. The third electrode 53 includes a first electrode portion 53a. The semiconductor member 10S is provided between the first electrode 51 and the second electrode 52.

A first direction D1 from the first electrode 51 to the second electrode 52 is defined as a Z-axis direction. One direction perpendicular to the Z-axis direction is defined as a Y-axis direction. A direction perpendicular to the Z-axis and Y-axis directions is defined as an X-axis direction.

The semiconductor member 10S includes a first semiconductor region 11 of a first conductivity type, a second semiconductor region 12 of a second conductivity type, a third semiconductor region 13 of the first conductivity type, a fourth semiconductor region 14 of the second conductivity type, and a fifth semiconductor region 15 of the second conductivity type. The first conductivity type is one of n-type and p-type. The second conductivity type is the other one of n-type and p-type. In the following, the first conductivity type is n-type, and the second conductivity type is p-type.

The first semiconductor region 11 may include, for example, a plurality of partial regions. The first semiconductor region 11 may include, for example, a first partial region 11a, a second partial region 11b, a third partial region 11c, and a fourth partial region 11d. The boundaries between these partial regions may be unclear or clear. These partial regions will be described later.

As shown in FIGS. 4 and 5, the fifth semiconductor region 15 may include a plurality of portions. For example, the fifth semiconductor region 15 includes a first semiconductor portion 15a and a second semiconductor portion 15b. The second semiconductor portion 15b is continuous with the first semiconductor portion 15a. As shown in FIG. 4, the second semiconductor portion 15b is electrically connected to the fourth semiconductor region 14. In the example of FIG. 4, the second semiconductor portion 15b is continuous with the fourth semiconductor region 14. The boundary between the second semiconductor portion 15b and the fourth semiconductor region 14 may be clear or unclear.

As shown in FIG. 1, the first partial region 11a is between the first electrode 51 and the first electrode portion 53a in the first direction D1 (the direction from the first electrode 51 to the second electrode 52). The second semiconductor region 12 is between the second partial region 11b of the first semiconductor region 11 and the third semiconductor region 13 in the first direction D1. A second direction D2 from the first electrode portion 53a to the second semiconductor region 12 crosses the first direction D1. The second direction D2 may be, for example, the Y-axis direction.

A direction from the first electrode portion 53a to the third semiconductor region 13 is along the second direction D2. The fourth semiconductor region 14 is between the first partial region 11a and the first electrode portion 53a.

In FIG. 6, an example of the pattern of the first insulating member 41 is shown by a solid line, and the pattern of the third electrode 53 is shown by a dashed line. In FIG. 7, an example of the pattern of the first insulating member 41 is shown by a dashed line, and the pattern of the third electrode 53 is shown by a solid line.

As shown in FIG. 4, a position of the first insulating member 41 in a third direction D3 crossing a plane including the first direction D1 and the second direction D2 (first insulating member position) is different from a position of the first electrode portion 53a in the third direction D3 (first electrode portion position). The third direction D3 may be, for example, the X-axis direction. For example, a direction from the first insulating member 41 to the first electrode portion 53a includes a component of the third direction D3.

As shown in FIG. 4, the first semiconductor portion 15a of the fifth semiconductor region 15 is between the third partial region 11c of the first semiconductor region 11 and the first insulating member 41. The second semiconductor portion 15b is between the first insulating member 41 and the fourth partial region 11d in a direction crossing the first direction D1.

A distance along the first direction D1 between the first electrode 51 and the fourth semiconductor region 14 is defined as a first distance d1. A distance along the first direction D1 between the first electrode 51 and the first semiconductor portion 15a is defined as a second distance d2. The first distance d1 is longer than the second distance d2. For example, a length L15b along the first direction D1 of the second semiconductor portion 15b is longer than a length L14 along the first direction D1 of the fourth semiconductor region 14.

As shown in FIG. 1, the semiconductor device 110 may include a second insulating member 42. The second insulating member 42 includes a first insulating portion 42a and a second insulating portion 42b. The first insulating portion 42a is between the first electrode portion 53a and the second semiconductor region 12, and between the first electrode portion 53a and the third semiconductor region 13. The second insulating portion 42b is between the fourth semiconductor region 14 and the first electrode portion 53a. The second electrode 52 is electrically connected to, for example, the third semiconductor region 13.

In the semiconductor device 110, current flowing between the first electrode 51 and the second electrode 52 can be controlled by a potential of the third electrode 53. The potential of the third electrode 53 may be, for example, a potential based on a potential of the second electrode 52. The first electrode 51 corresponds, for example, to a drain electrode. The second electrode 52 corresponds, for example, to a source electrode. The third electrode 53 corresponds, for example, to a gate electrode. The semiconductor device 110 is, for example, a transistor. The semiconductor device 110 may be, for example, a MOS type transistor.

In the semiconductor device 110, by providing the fourth semiconductor region 14 of the second conductivity type, for example, the concentration of the electric field strength can be suppressed. This makes it easier to obtain a high breakdown voltage, for example. For example, the electric field applied to the second insulating member 42 (for example, the gate oxide film) can be reduced.

In the semiconductor device 110, a superjunction structure is formed by the fifth semiconductor region 15 of the second conductivity type and at least a part of the first semiconductor region 11 (for example, the fourth partial region 11d). For example, it is easy to increase the concentration of impurities of the first conductivity type in the first semiconductor region 11. For example, a low on-resistance is obtained. A semiconductor device capable of improving characteristics is provided.

In the embodiment, the fifth semiconductor region 15 is provided between the first insulating member 41 and the first semiconductor region 11 at a position different from the first electrode portion 53a that contributes to switching. Stable characteristics are easily obtained in such a fifth semiconductor region 15. For example, the potential of the fifth semiconductor region 15 can be made substantially the same as the potential of the fourth semiconductor region 14. In one example, a deep trench may be formed in the first semiconductor region 11, and impurities of the second conductivity type may be introduced into the side face of the trench. The remaining space in the trench may then be filled with the first insulating member 41.

In a first reference example, an attempt is made to obtain the fifth semiconductor region 15 by introducing an impurity of the second conductivity type into a deep position of the first semiconductor region 11. In the first reference example, it is difficult to uniformly and stably introduce an impurity of the second conductivity type into a deep position. In the second reference example, it is difficult to obtain stable characteristics.

In a second reference example, a deep trench is formed in the first semiconductor region 11, and an attempt is made to fill the trench with a semiconductor of the second conductivity type. In the second reference example, it is difficult to stably fill the deep trench with the semiconductor. In the first reference example, it is difficult to obtain stable characteristics.

As a third reference example, a configuration is considered in which a second conductivity type (p-type) region is provided deep below the first electrode portion 53a that contributes to switching. In the third reference example, the second conductivity type region has a floating structure, making it difficult to obtain stable characteristics.

In the embodiment, by the fifth semiconductor region 15 being stable, it becomes possible to stably obtain the semiconductor device 110 with improved characteristics.

As shown in FIG. 4, the first semiconductor portion 15a is continuous with the second semiconductor portion 15b. The fifth semiconductor region 15 may further include a third semiconductor portion 15c. The first insulating member 41 is between the third semiconductor portion 15c and the second semiconductor portion 15b.

As shown in FIG. 1, a length of the first electrode portion 53a along the second direction D2 is defined as a first length L1. As shown in FIGS. 4 and 5, a length of the first insulating member 41 along the third direction D3 is defined as a second length L2. The second length L2 is longer than the first length L1. By the second length L2 being long, it becomes easier to obtain the fifth semiconductor region 15 being stable, for example. For example, when a trench for the first electrode portion 53a and a trench for the first insulating member 41 are formed with the same aspect ratio, the second length L2 being long allows the trench for the first insulating member 41 to be made deeper.

For example, the second length L2 along the third direction D3 of the first insulating member 41 may be longer than a third length L3 along the third direction D3 of the second semiconductor portion 15b. By the second length L2 being long, it becomes easier to obtain, for example, the fifth semiconductor region 15 being stable. For example, the third length L3 being long can be easily obtained stably by ion implantation.

As shown in FIG. 1, a plurality of first electrode portions 53a may be provided. The plurality of first electrode portions 53a are arranged along the second direction D2. As shown in FIG. 7, in this example, the plurality of third electrodes 53 are provided. Each of the plurality of third electrodes 53 is in a shape of a strip extending along the third direction D3. The plurality of third electrodes 53 are arranged along the second direction D2.

As shown in FIGS. 4 and 5, a plurality of first insulating members 41 may be provided. The plurality of first insulating members 41 are arranged along the third direction D3. As shown in FIG. 6, in this example, each of the plurality of first insulating members 41 is in a shape of a strip extending along the second direction D2. The plurality of first insulating members 41 are arranged along the third direction D3.

In the embodiment, a fifth impurity concentration of the second conductivity type in the fifth semiconductor region 15 may be equal to or lower than a second impurity concentration of the second conductivity type in the second semiconductor region 12. The fifth impurity concentration may be, for example, not less than 1×10¹⁶ cm⁻³ and not more than 8×10¹⁷ cm⁻³. The second impurity concentration may be, for example, not less than 5×10¹⁶ cm⁻³ and not more than 1×10¹⁸ cm⁻³. A fourth impurity concentration of the second conductivity type in the fourth semiconductor region 14 may be, for example, not less than 5×10¹⁶ cm⁻³ and not more than 1×10¹⁸ cm⁻³.

A first impurity concentration of the first conductivity type in the first semiconductor region 11 may be, for example, not less than 1×10¹⁵ cm⁻³ and not more than 5×10¹⁷ cm⁻³. A third impurity concentration of the first conductivity type in the third semiconductor region 13 may be, for example, not less than 1×10¹⁸ cm⁻³ and not more than 1×10²¹ cm⁻³.

As shown in FIG. 1, the semiconductor member 10S may include a sixth semiconductor region 16 of the first conductivity type. At least a part of the sixth semiconductor region 16 is provided between the second partial region 11b and the second semiconductor region 12 in the first direction D1. A sixth impurity concentration of the first conductivity type in the sixth semiconductor region 16 may be higher than the first impurity concentration of the first conductivity type in the first semiconductor region 11. The sixth semiconductor region 16 may be omitted.

As shown in FIG. 1, the semiconductor member 10S may further include a seventh semiconductor region 17 of the second conductivity type and an eighth semiconductor region 18 of the first conductivity type. At least a part of the second semiconductor region 12 is between the first electrode portion 53a and the seventh semiconductor region 17. At least a part of the third semiconductor region 13 is between the first electrode portion 53a and the eighth semiconductor region 18. The eighth semiconductor region 18 is between the seventh semiconductor region 17 and the second electrode 52. For example, a seventh impurity concentration of the second conductivity type in the seventh semiconductor region 17 is higher than the second impurity concentration of the second conductivity type in the second semiconductor region 12. For example, an eighth impurity concentration of the first conductivity type in the eighth semiconductor region 18 is higher than the third impurity concentration of the first conductivity type in the third semiconductor region 13. A low electrical resistance is obtained between the second electrode 52 and the semiconductor member 10S.

As shown in FIG. 1, in this example, the third semiconductor region 13 (and the eighth semiconductor region 18) is between the first electrode portion 53a and a part 52p of the second electrode 52. The first electrode portion 53a is between the semiconductor member 10S and another part 52q of the second electrode 52. A part of the second insulating member 42 is between the first electrode portion 53a and another part 52q of the second electrode 52.

As shown in FIG. 1, in this example, the semiconductor member 10S further includes a semiconductor layer 10a of the first conductivity type. The semiconductor layer 10a is between the first electrode 51 and a first semiconductor region 11. An impurity concentration of the first conductivity type in the semiconductor layer 10a is higher than the first impurity concentration of the first conductivity type in the first semiconductor region 11. A low electrical resistance is obtained between the first electrode 51 and the semiconductor member 10S. The semiconductor layer 10a may be a semiconductor substrate.

The semiconductor member 10S may include SiC or Si. The semiconductor member 10S may include, for example, at least one selected from the group consisting of 4H—SiC, 6H—SiC, and 3C—SiC. In a case where the semiconductor member 10S includes SiC, the impurities of the first conductivity type include, for example, at least one selected from the group consisting of N, P, and As. In a case where the semiconductor member 10S includes SiC, the impurities of the second conductivity type include, for example, at least one selected from the group consisting of B, Al, and Ga. The semiconductor member 10S may include, for example, a compound semiconductor including Ga.

The semiconductor member 10S includes a crystal. The first electrode portion 53a of the third electrode 53 includes a side face 53s facing the second semiconductor region 12 and the third semiconductor region 13 (see FIG. 1). The side face 53s may be along the <11-20> direction of the crystal, for example. For example, a lower on-resistance is easily obtained. For example, the face of the semiconductor region facing the side face 53s can have the same plane orientation. For example, a symmetrical trench shape can be obtained. Thereby, it becomes possible to further reduce the on-resistance.

The first electrode 51 may include at least one selected from the group consisting of Ti, Ni, and Au. The first electrode 51 may include a laminated film including these materials. The second electrode 52 may include at least one selected from the group consisting of Al, Cu, Ti, and W, for example. The third electrode 53 may include, for example, conductive polysilicon.

The first insulating member 41 may include at least one selected from the group consisting of silicon oxide, resin, and polysilicon. The resin may include, for example, polyimide. A concentration of the conductivity-imparting impurity in the polysilicon included in the first insulating member 41 may be, for example, 1×10¹⁶ cm⁻³ or less.

As shown in FIG. 4, the third electrode 53 may further include a second electrode portion 53b. A direction from the second electrode portion 53b to the first electrode portion 53a is along the third direction D3. A direction from at least a part of the first insulating member 41 to the second electrode portion 53b is along the first direction D1. In this example, the third electrode 53 is strip-shaped and extends along the third direction D3. The third electrode 53 being strip-shaped passes above the plurality of first insulating members 41.

As shown in FIG. 2, the second electrode portion 53b is located in the second direction D2 between a part of the first insulating member 41 and another part of the first insulating member 41. The first insulating member 41 is in the shape of a band extending along the second direction D2.

As already described, the semiconductor device 110 may include the second insulating member 42. The second insulating member 42 includes a first insulating portion 42a and a second insulating portion 42b. The second insulating portion 42b is provided between the first insulating member 41 and the second electrode portion 53b.

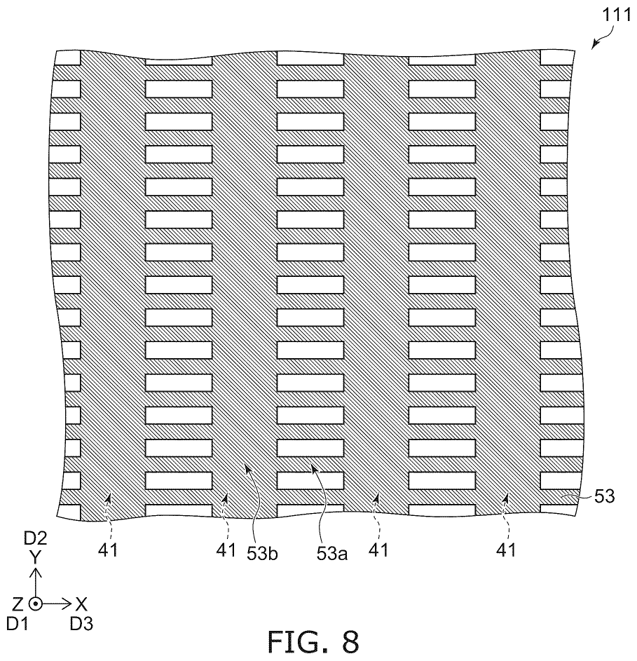

FIG. 8 is a schematic plan view illustrating a semiconductor device according to the first embodiment.

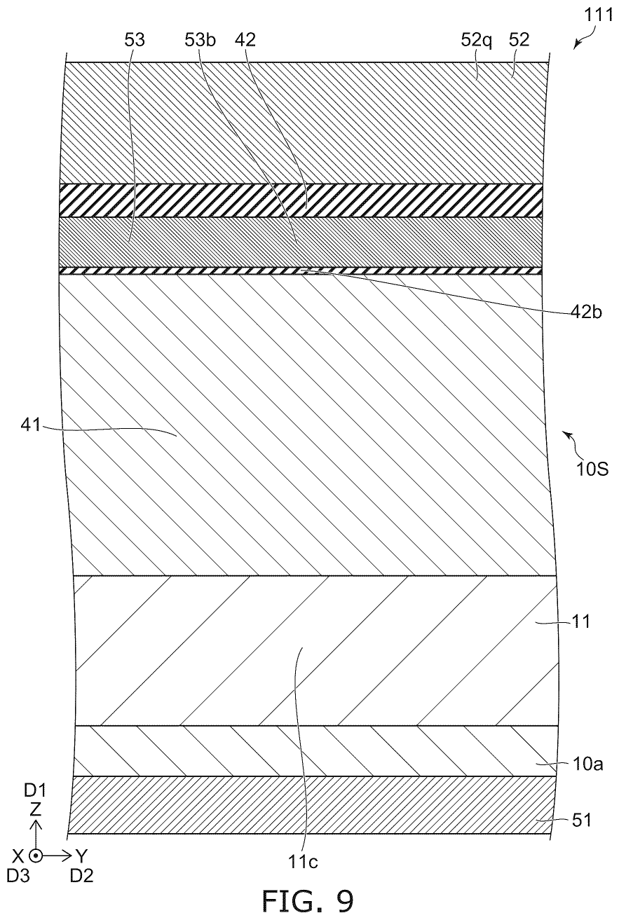

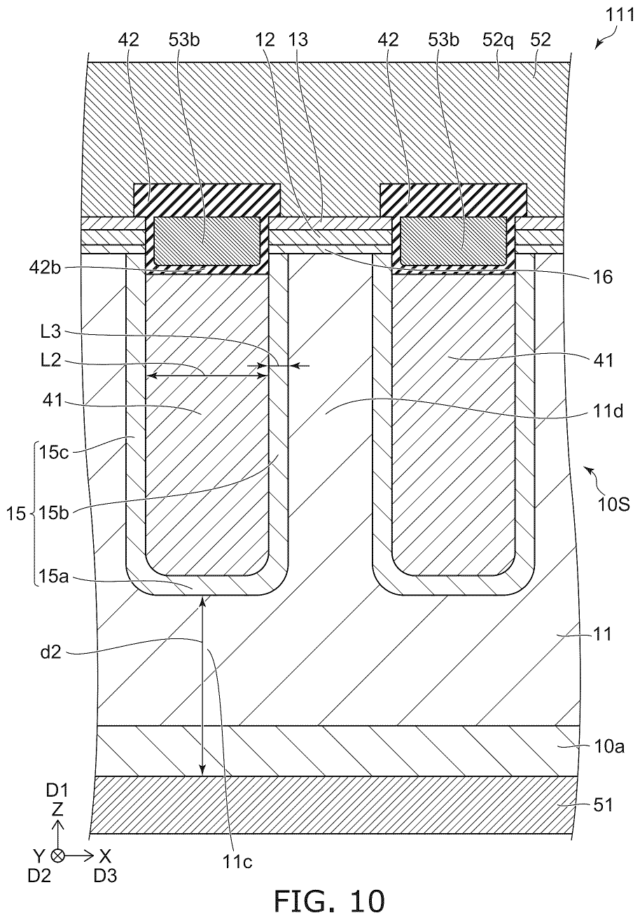

FIGS. 9 and 10 are schematic cross-sectional views illustrating the semiconductor device according to the first embodiment.

FIG. 9 is a cross-sectional view corresponding to the line B3-B4 in FIG. 6. FIG. 10 is a cross-sectional view corresponding to the line A3-A4 in FIG. 6. FIG. 8 is a schematic plan view illustrating the pattern of third electrode 53. As shown in FIG. 8, in a semiconductor device 111 according to the embodiment, the planar shape of third electrode 53 is a lattice shape. Except for this, the configuration of semiconductor device 111 may be the same as the configuration of semiconductor device 110.

As shown in FIG. 8, in the semiconductor device 111, the third electrode 53 has a lattice shape including a portion extending along the second direction D2 and a portion extending along the third direction D3. The portion extending along the second direction D2 corresponds to, for example, the first electrode portion 53a. The portion extending along the third direction D3 corresponds to, for example, the second electrode portion 53b.

In the semiconductor device 111, the plurality of first insulating members 41 may be provided (see FIG. 6). Each of the plurality of first insulating members 41 is strip-shaped and extends along the second direction D2. The plurality of first insulating members 41 are arranged along the third direction D3. A part of the third electrode 53 (second electrode portion 53b) being lattice-shaped overlap the plurality of first insulating members 41 in the first direction D1.

As shown in FIGS. 9 and 10, the second insulating portion 42b is provided between the second electrode portion 53b included in the third electrode 53 and the first insulating member 41. The fourth semiconductor region 14 and the fifth semiconductor region 15 are also provided in the semiconductor device 111. For example, a high breakdown voltage is easily obtained. For example, a low on-resistance is obtained. A semiconductor device capable of improving characteristics is provided.

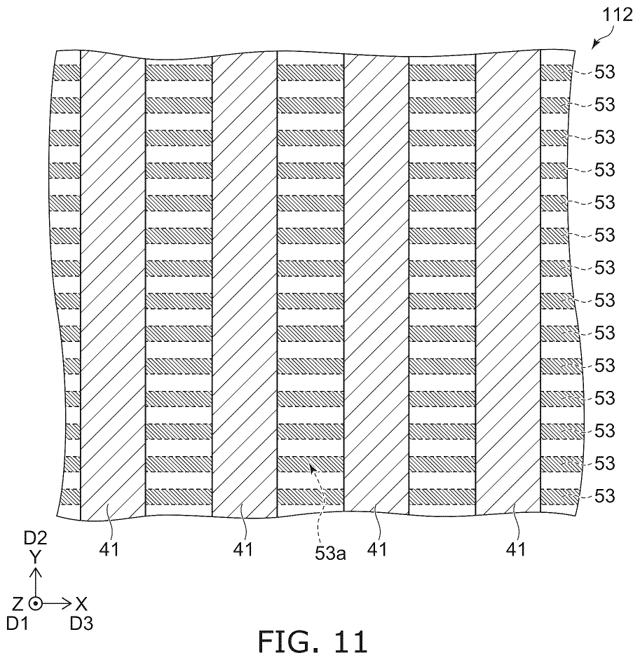

FIG. 11 is a schematic plan view illustrating a semiconductor device according to the first embodiment.

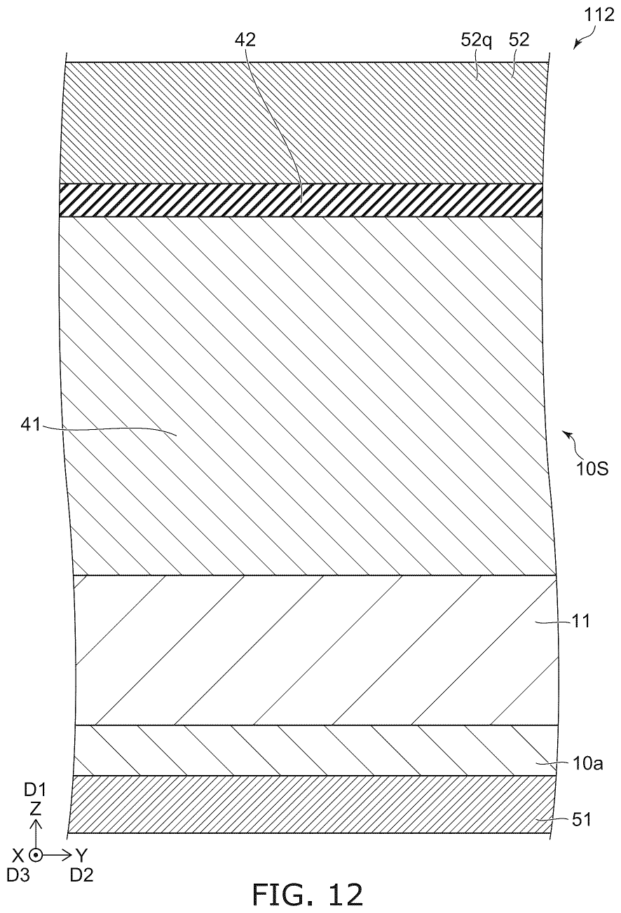

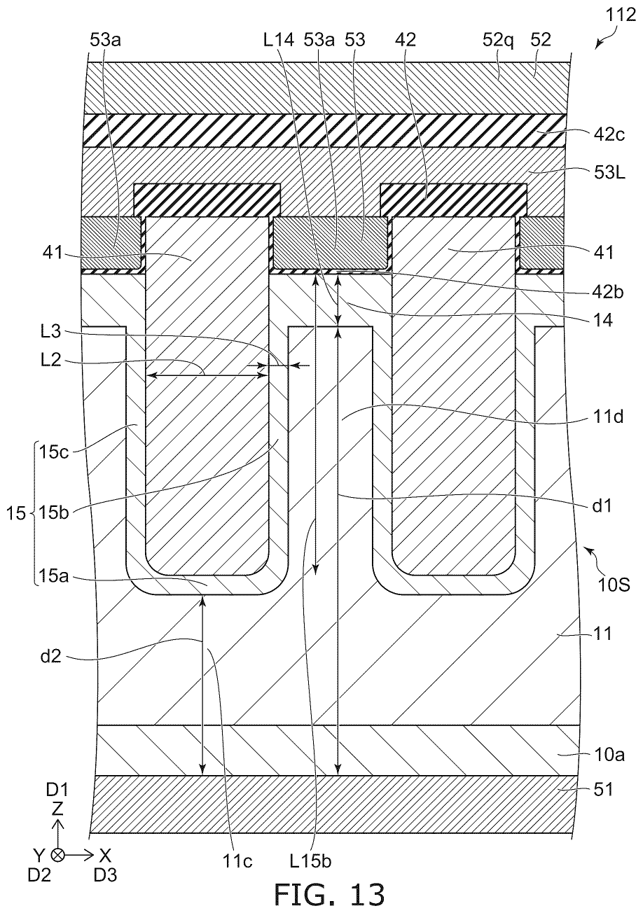

FIGS. 12 and 13 are schematic cross-sectional views illustrating the semiconductor device according to the first embodiment.

FIG. 12 is a cross-sectional view corresponding to the line B3-B4 in FIG. 6. FIG. 13 is a cross-sectional view corresponding to the line A1-A2 in FIG. 6. FIG. 11 illustrates the patterns of the first insulating member 41 and the third electrode 53. As shown in FIG. 11, in a semiconductor device 112 according to the embodiment, the first insulating member 41 is strip-shaped, and the third electrode 53 is island-shaped. Except for this, the configuration of the semiconductor device 112 may be the same as the configuration of the semiconductor device 110.

As shown in FIG. 11, the plurality of first insulating members 41 are provided. Each of the plurality of first insulating members 41 is in the shape of a band along the second direction D2. The plurality of first insulating members 41 are aligned along the third direction D3. The plurality of first electrode portions 53a are provided. The plurality of first electrode portions 53a are arranged along the second direction D2 and the third direction D3. One of the plurality of first electrode portions 53a is located between one of the plurality of first insulating members 41 and another one of the plurality of first insulating members 41 in the third direction D3.

As shown in FIG. 13, a direction from a part of the first insulating member 41 to the first electrode portion 53a is along the third direction D3. The part of the first insulating member 41 is between one of the plurality of first electrode portions 53a and another one of the plurality of first electrode portions 53a in the third direction D3. The fourth semiconductor region 14 and the fifth semiconductor region 15 described above are also provided in the semiconductor device 112. For example, a high breakdown voltage is easily obtained. For example, a low on-resistance is obtained. A semiconductor device capable of improving characteristics is provided.

As shown in FIG. 13, a third electrode wiring 53L may be provided that is electrically connected to the first electrode portion 53a. A third insulating portion 42c of the second insulating member 42 may be provided between the third electrode wiring 53L and the second electrode 52.

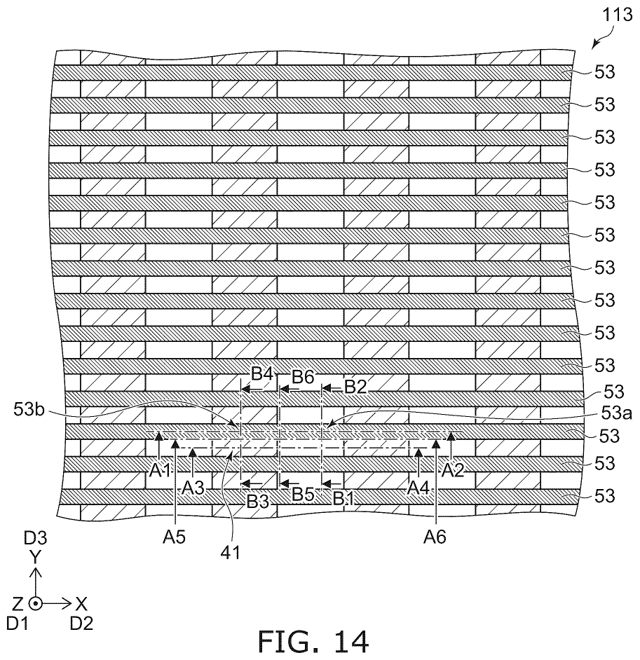

FIG. 14 is a schematic plan view illustrating a semiconductor device of the first embodiment.

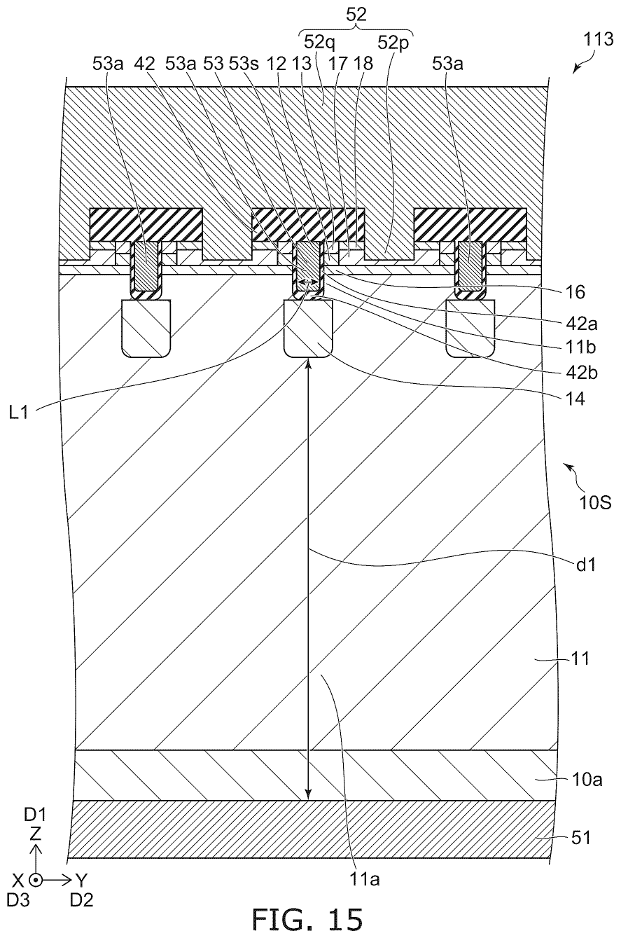

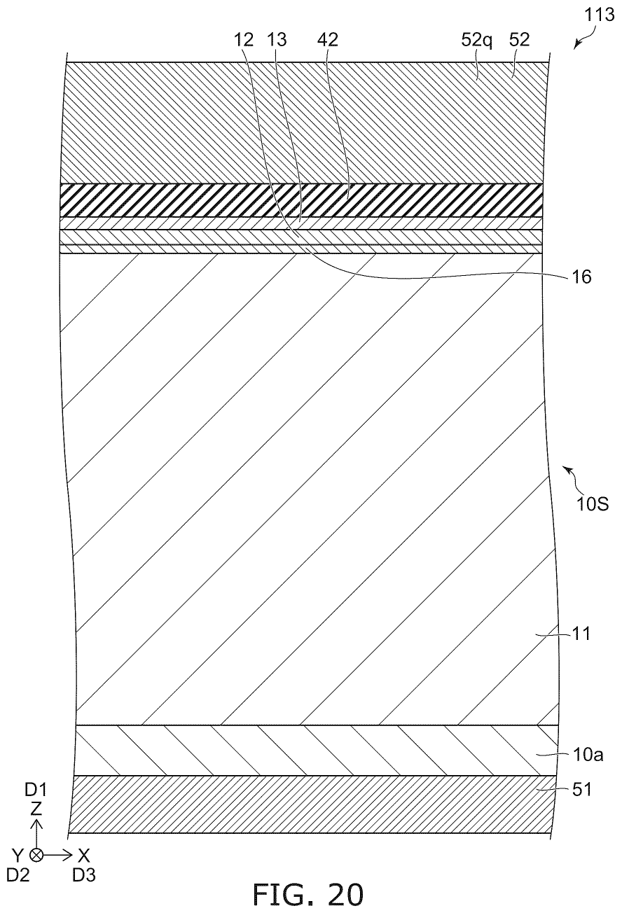

FIGS. 15 to 20 are schematic cross-sectional views illustrating the semiconductor device of the first embodiment.

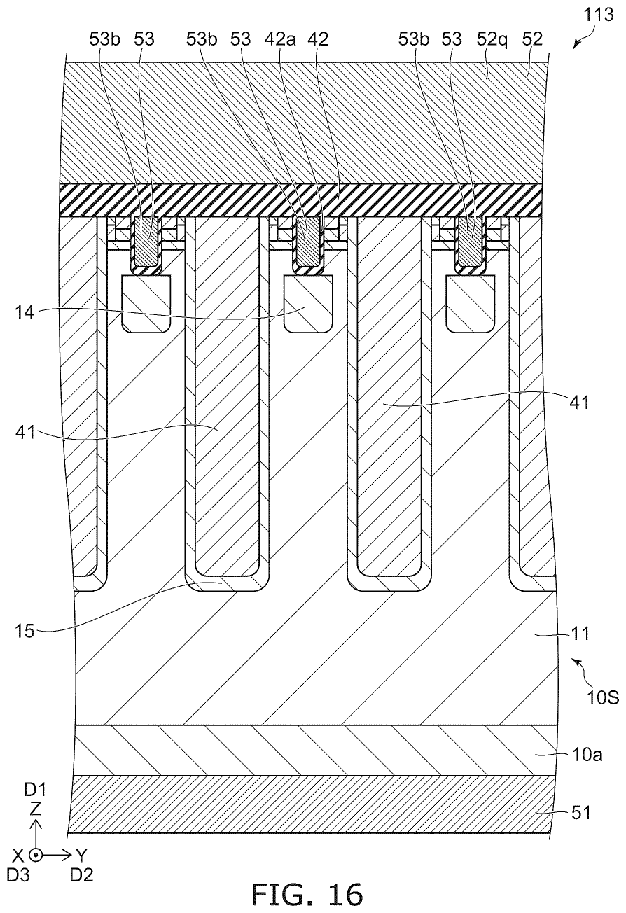

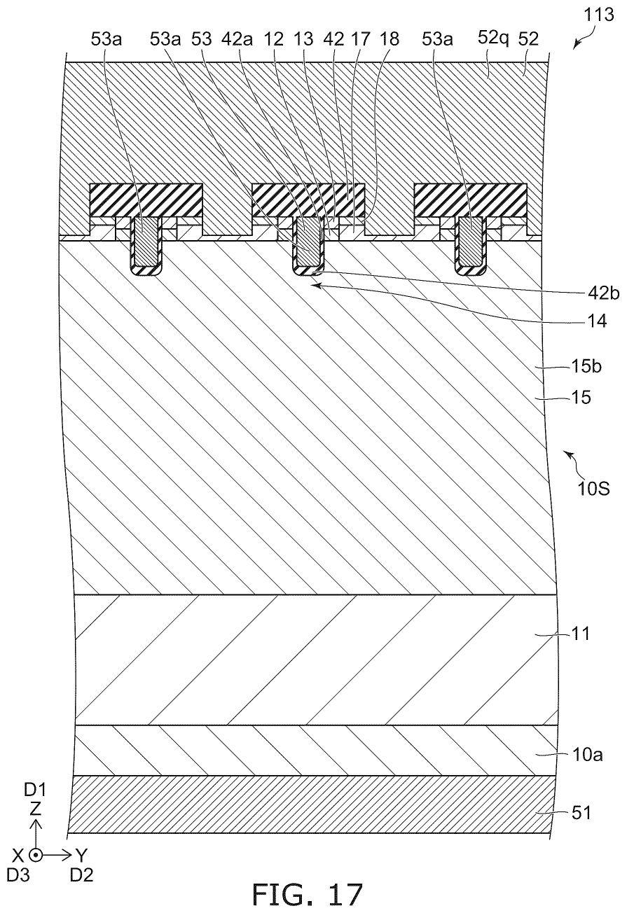

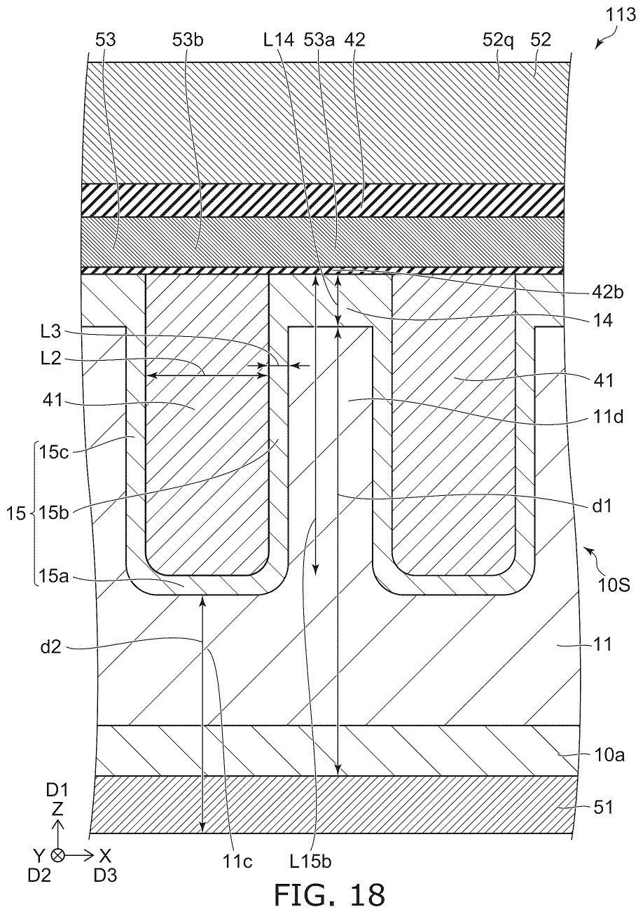

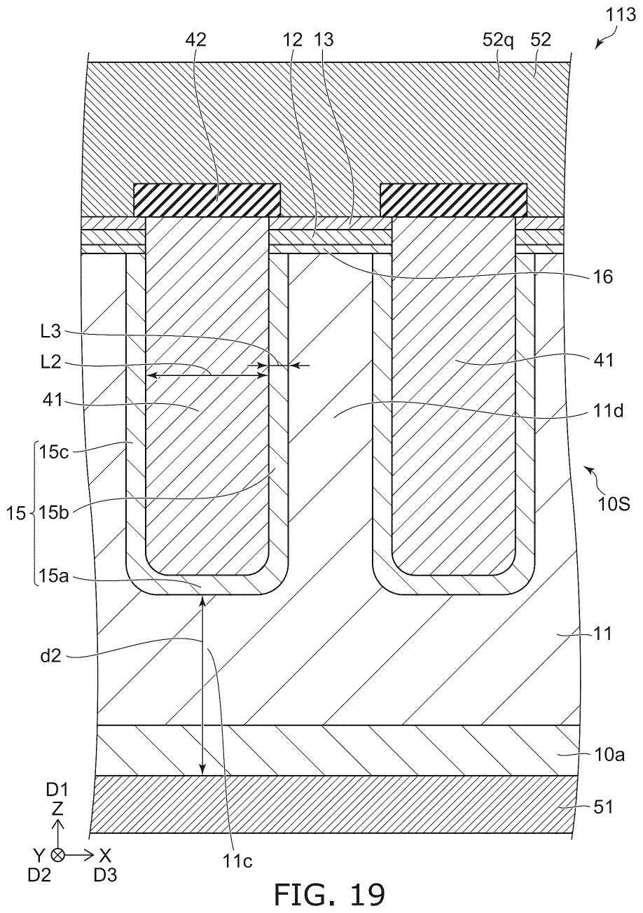

FIG. 15 is a cross-sectional view taken along the line B1-B2 in FIG. 14. FIG. 16 is a cross-sectional view taken along the line B3-B4 in FIG. 14. FIG. 17 is a cross-sectional view taken along the line B5-B6 in FIG. 14. FIG. 18 is a cross-sectional view taken along the line A1-A2 in FIG. 14. FIG. 19 is a cross-sectional view taken along the line A3-A4 in FIG. 14.

As shown in FIG. 14, in a semiconductor device 113 according to the embodiment, the first insulating members 41 are island-shaped, and each of the third electrodes 53 is strip-shaped. Except for this. the configuration of the semiconductor device 113 may be the same as the configuration of the semiconductor device 110, for example.

As shown in FIG. 14, the plurality of third electrodes 53 are provided in the semiconductor device 113. Each of the plurality of third electrodes 53 extends along the third direction D3. As shown in FIG. 16, each of the plurality of third electrodes 53 includes a second electrode portion 53b. A part of the first insulating member 41 is between the second electrode portion 53b of one of the plurality of third electrodes 53 and the second electrode portion 53b of another one of the plurality of third electrodes 53 in the second direction D2.

As shown in FIG. 16, the plurality of first insulating members 41 are provided. The third electrode 53 includes the second electrode portion 53b. As shown in FIGS. 14 and 18, the direction from the second electrode portion 53b to the first electrode portion 53a is along the third direction D3 crossing a plane including the first direction D1 and the second direction D2. As shown in FIG. 16, the second electrode portion 53b is between a part of one of the plurality of first insulating members 41 and a part of another one of the plurality of first insulating members 41 in the second direction D2.

As shown in FIG. 14, in the semiconductor device 113, the direction from the first insulating member 41 to the first electrode portion 53a is inclined with respect to the second direction D2. The direction from the first insulating member 41 to the first electrode portion 53a is inclined with respect to the direction from the second electrode portion 53b to the first electrode portion 53a.

The semiconductor device 113 also has the fourth semiconductor region 14 and the fifth semiconductor region 15. For example, a high breakdown voltage is easily obtained. For example, a low on-resistance is obtained. A semiconductor device with improved characteristics is provided.

In semiconductor devices 110 to 113, the sixth semiconductor region 16 may be omitted.

### Second Embodiment

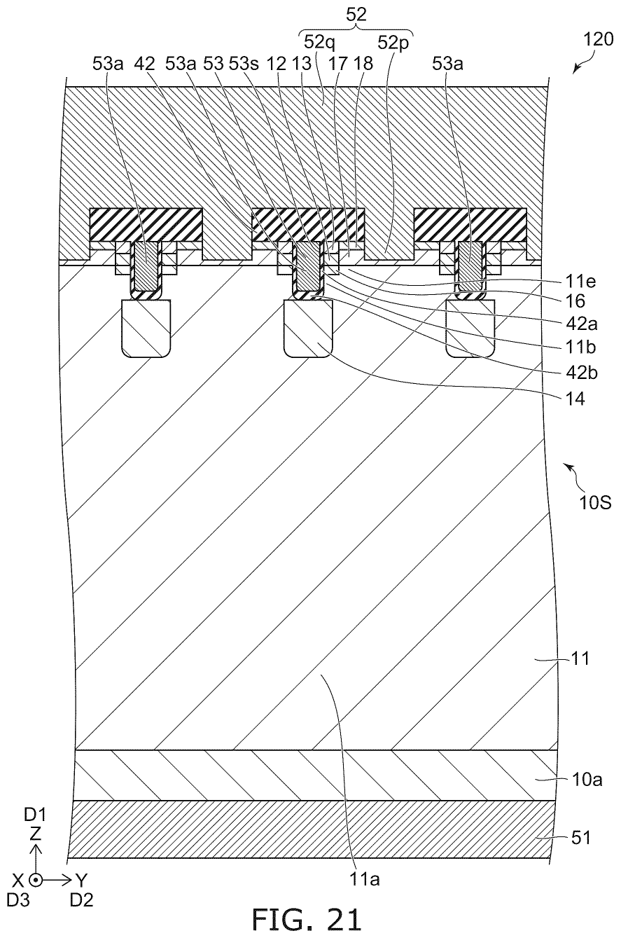

FIG. 21 is a schematic cross-sectional view illustrating a semiconductor device according to the second embodiment.

FIG. 21 is a cross-sectional view corresponding to, for example, the line B1-B2 in FIG. 6. As shown in FIG. 21, in a semiconductor device 120 according to the embodiment, the sixth semiconductor region 16 included in the semiconductor member 10S is provided between the first electrode portion 53a and a part of the first semiconductor region 11 (for example, the fifth partial region 11e) in the second direction D2. In the semiconductor device 120, for example, a high breakdown voltage is easily obtained. For example, a low on-resistance is obtained. A semiconductor device capable of improving characteristics is provided. The configuration described with respect to the semiconductor device 120 may be applied to any semiconductor device according to the first embodiment.

In the embodiment, information regarding length and thickness is obtained by observation using an electron microscope, etc. Information regarding the composition of the material is obtained by SIMS (Secondary Ion Mass Spectrometry) or EDX (Energy dispersive X-ray spectroscopy), etc.

According to the embodiment, a semiconductor device with improved characteristics can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode;
a semiconductor member provided between the first electrode and the second electrode;
a third electrode including a first electrode portion; and
a first insulating member,
the semiconductor member including:
a first semiconductor region of a first conductivity type, the first semiconductor region including a first partial region, a second partial region, a third partial region, and a fourth partial region;
a second semiconductor region of a second conductivity type;
a third semiconductor region of the first conductivity type;
a fourth semiconductor region of the second conductivity type; and
a fifth semiconductor region of the second conductivity type, the fifth semiconductor region including a first semiconductor portion and a second semiconductor portion continuous with the first semiconductor portion, the second semiconductor portion being electrically connected to the fourth semiconductor region,
the first partial region being between the first electrode and the first electrode portion in a first direction from the first electrode to the second electrode,
the second semiconductor region being between the second partial region and the third semiconductor region in the first direction,
a second direction from the first electrode portion to the second semiconductor region crossing the first direction,
a direction from the first electrode portion to the third semiconductor region being along the second direction,
the fourth semiconductor region being between the first partial region and the first electrode portion,
a first insulating member position of the first insulating member in a third direction crossing a plane including the first direction and the second direction being different from a first electrode portion position of the first electrode portion in the third direction,
the first semiconductor portion being between the third partial region and the first insulating member,
the second semiconductor portion being between the first insulating member and the fourth partial region in a direction crossing the first direction,
a first distance along the first direction between the first electrode and the fourth semiconductor region being longer than a second distance along the first direction between the first electrode and the first semiconductor portion.

2. The semiconductor device according to claim 1, wherein
the first semiconductor portion is continuous with the second semiconductor portion.

3. The semiconductor device according to claim 1, wherein
a fifth impurity concentration of the second conductivity type in the fifth semiconductor region is equal to or lower than a second impurity concentration of the second conductivity type in the second semiconductor region.

4. The semiconductor device according to claim 1, wherein
the first insulating member includes at least one selected from the group consisting of silicon oxide, resin, and polysilicon, and
a concentration of the conductive impurity in the polysilicon is 1×10¹⁶ cm⁻³ or less.

5. The semiconductor device according to claim 1, wherein
a second length of the first insulating member along the third direction is longer than a first length of the first electrode portion along the second direction.

6. The semiconductor device according to claim 1, wherein
a second length of the first insulating member along the second direction is longer than a third length of the second semiconductor portion along the second direction.

7. The semiconductor device according to claim 1, wherein
the semiconductor member includes a crystal,
the first electrode portion includes a side face facing the second semiconductor region and the third semiconductor region,
the side face is along the <11-20> direction of the crystal.

8. The semiconductor device according to claim 1, wherein
the semiconductor member includes SiC.

9. The semiconductor device according to claim 1, further comprising:
a second insulating member including a first insulating portion and a second insulating portion,
the first insulating portion being between the first electrode portion and the second semiconductor region, and between the first electrode portion and the third semiconductor region, and
the second insulating portion being between the fourth semiconductor region and the first electrode portion.

10. The semiconductor device according to claim 9, wherein
a part of the second insulating member is provided between the first electrode portion and the second electrode.

11. The semiconductor device according to claim 1, wherein
a plurality of the first electrode portions are provided, and
the plurality of the first electrode portions are arranged along the second direction.

12. The semiconductor device according to claim 1, wherein
a plurality of the first insulating members are provided, and
the plurality of the first insulating members are arranged along the third direction.

13. The semiconductor device according to claim 1, wherein
the third electrode further includes a second electrode portion,
a direction from the second electrode portion to the first electrode portion is along the third direction, and
a direction from at least a part of the first insulating member to the second electrode portion is along the first direction.

14. The semiconductor device according to claim 13, further comprising:
the second insulating member including a first insulating portion and a second insulating portion,
the second insulating portion being provided between the first insulating member and the second electrode portion.

15. The semiconductor device according to claim 13, wherein
the third electrode has a lattice shape including a portion extending along the second direction and a portion extending along the third direction.

16. The semiconductor device according to claim 1, wherein
a direction from a part of the first insulating member to the first electrode portion is along the third direction.

17. The semiconductor device according to claim 1, wherein
the third electrode includes a plurality of the first electrode portions, and
a part of the first insulating member is between one of the plurality of the first electrode portions and another one of the plurality of the first electrode portions in the third direction.

18. The semiconductor device according to claim 1, wherein
a plurality of the third electrodes are provided,
each of the plurality of the third electrodes further includes a second electrode portion, and
a part of the first insulating member is between the second electrode portion of one of the plurality of third electrodes and the second electrode portion of another one of the plurality of third electrodes in the second direction.

19. The semiconductor device according to claim 1, wherein
a plurality of the first insulating members are provided,
the third electrode further includes a second electrode portion,
a direction from the second electrode portion to the first electrode portion is along the third direction, and
the second electrode portion is between a part of one of the plurality of first insulating members and a part of another one of the plurality of first insulating members in the second direction.

20. The semiconductor device according to claim 1, wherein
a direction from the first insulating member to the first electrode portion is inclined with respect to the second direction.
